(19) United States
(12) Patent Application Publication
(10) Pub. No.: US 2026/0075942 A1
(43) Pub. Date: Mar. 12, 2026

(54) DISPLAY PANEL, ELECTRONIC DEVICE, METHOD FOR MANUFACTURING DISPLAY PANEL

(71) Applicant: Samsung Display Co., Ltd., Yongin-si (KR)

(72) Inventors: SANGWOO SOHN, Yongin-si (KR); Kyung-Tae KIM, Yongin-si (KR); YEON KEON MOON, Yongin-si (KR); CHULWON PARK, Yongin-si (KR); JUN HYUNG LIM, Yongin-si (KR); Hyunjun JEONG, Yongin-si (KR)

(73) Assignee: Samsung Display Co., Ltd., Yongin-si (KR)

(21) Appl. No.: 19/242,158

(22) Filed: Jun. 18, 2025

(30) Foreign Application Priority Data
Sep. 10, 2024 (KR) 10-2024-0122878

(51) Int. Cl. H10D 86/40; H10D 86/60

(52) U.S. Cl. CPC H10D 86/423; H10D 86/427; H10D 86/60

(57) ABSTRACT

A display panel includes a light emitting element on a base layer, and a pixel driving circuit electrically connected to the light emitting element. The pixel driving circuit includes a first transistor including a first oxide semiconductor pattern and a second transistor including a second oxide semiconductor pattern. The first oxide semiconductor pattern includes a first channel region including a first oxide semiconductor layer and a second oxide semiconductor layer on the first oxide semiconductor layer, and the second oxide semiconductor pattern includes a second channel region including a single-layer oxide semiconductor layer.

### CROSS-REFERENCE TO RELATED APPLICATION(S)

This application claims priority to and benefits of Korean Patent Application No. 10-2024-0122878 under 35 U.S.C. § 119, filed on Sep. 10, 2024, in the Korean Intellectual Property Office (KIPO), the entire contents of which are incorporated herein by reference.

### BACKGROUND

### 1. Technical Field

Embodiments of the disclosure described herein relate to a display panel, which is improved in display characteristic, an electronic device including the display panel, and a method for manufacturing the display panel.

### 2. Description of the Related Art

A display device includes a display panel, and the display panel includes multiple pixels and a pixel driving circuit (for example, a scan driving circuit, and a data driving circuit) for controlling an electrical signal applied to the pixels. The pixel driving circuit may include multiple transistors systematically connected to each other. The transistors may include a silicon semiconductor or an oxide semiconductor.

### SUMMARY

Embodiments of the disclosure provide a display panel including an oxide transistor having a higher mobility and a wider range in a driving voltage, and an electronic device including the display panel.

Embodiments of the disclosure provide a method for manufacturing the display panel including the oxide transistor.

According to an embodiment of the disclosure, a display panel may include a light emitting element on a base layer, and a pixel driving circuit electrically connected to the light emitting element. The pixel driving circuit may include a first transistor including a first oxide semiconductor pattern and a second transistor including a second oxide semiconductor pattern. The first oxide semiconductor pattern may include a first channel region including a first oxide semiconductor layer and a second oxide semiconductor layer on the first oxide semiconductor layer, and the second oxide semiconductor pattern may include a second channel region including a single-layer oxide semiconductor layer.

The first transistor may further include a first gate disposed on the second oxide semiconductor layer and overlapping the first channel region in a plan view, and a first gate insulating layer interposed between the first gate and the second oxide semiconductor layer.

The second oxide semiconductor layer and the single-layer oxide semiconductor layer may include a same semiconductor material.

The second transistor may output a data voltage, and the first transistor may control a driving current of the light emitting element to correspond to the data voltage.

The first oxide semiconductor pattern may have a thickness greater than or equal to about 250 Å, and the second oxide semiconductor pattern may have a thickness less than or equal to about 200 Å.

The first oxide semiconductor layer and the second oxide semiconductor layer may include different oxide semiconductors, and the first oxide semiconductor layer may include an indium-gallium-zinc-oxide (IGZO).

The second oxide semiconductor layer may include indium, tin, gallium, zinc, and oxygen (ITGZO).

In the second oxide semiconductor layer, the indium may have a composition ratio in a range of about 60 w % to about 80 wt %, the tin may have a composition ratio in a range of about 0.5 wt % to about 8 wt %, the gallium may have a composition ratio in a range of about 5 wt % to about 15 wt %, and the zinc may have a composition ratio in a range of about 10 wt % to about 30 wt %.

The display panel may further include a lower metal layer interposed between the base layer and the first transistor, and a buffer layer interposed between the lower metal layer and the first oxide semiconductor pattern. The first oxide semiconductor pattern and the second oxide semiconductor pattern may be disposed on the buffer layer.

A source of the first transistor may be electrically connected to the lower metal layer.

A first connecting electrode that connects the source of the first transistor to the lower metal layer, and a second connecting electrode connected to a source of the second transistor may be disposed on a same layer.

Each of the first transistor and the second transistor may have a top-gate structure.

According to an embodiment of the disclosure, an electronic device may include a light emitting element on a base layer, and a pixel driving circuit electrically connected to the light emitting element. The pixel driving circuit may include a first transistor including a first oxide semiconductor pattern and a second transistor including a second oxide semiconductor pattern. The first oxide semiconductor pattern may include a first channel region including a first oxide semiconductor layer and a second oxide semiconductor layer on the first oxide semiconductor layer, and the second oxide semiconductor pattern may include a second channel region including a single-layer oxide semiconductor layer.

The first oxide semiconductor pattern may have a thickness greater than or equal to about 250 Å, and the second oxide semiconductor pattern may have a thickness less than or equal to about 200 Å.

The first oxide semiconductor layer and the second oxide semiconductor layer may include different oxide semiconductors, and the first oxide semiconductor layer may include an indium-gallium-zinc-oxide (IGZO).

According to an embodiment of the disclosure, a method for manufacturing a display panel may include forming a first oxide semiconductor layer on a base layer, forming a second oxide semiconductor layer including a first region overlapping the first oxide semiconductor layer, and a second region non-overlapping the first oxide semiconductor layer in a plan view, on the base layer, forming a first gate overlapping the first region of the second oxide semiconductor layer in a plan view, forming a second gate overlapping a second region of the second oxide semiconductor layer in a plan view, and forming an insulating layer to cover the first gate and the second gate.

The first oxide semiconductor layer may have a thickness greater than or equal to about 50 Å, and the second oxide semiconductor layer may have a thickness less than or equal to about 200 Å.

The method may further include forming a lower metal layer between the base layer and the first oxide semiconductor layer, and forming a buffer layer to cover the lower metal layer and the base layer.

The forming of the first gate may include forming a first channel region overlapping the first gate in a plan view and a first source region and a first drain region disposed at opposite sides of the first channel region from the second oxide semiconductor layer.

The lower metal layer may overlap the first region in a plan view, and the lower metal layer and the first source region may be electrically connected to each other.

### BRIEF DESCRIPTION OF THE DRAWINGS

The above and other objects and features of the disclosure will become apparent by describing in detail embodiments thereof with reference to the accompanying drawings.

FIG. 1 is a perspective view of a display device according to an embodiment of the disclosure.

FIG. 2 is a schematic cross-sectional view of a display device illustrated in FIG. 1.

FIG. 3 is a schematic cross-sectional view of a display panel illustrated in FIG. 2.

FIG. 4 is a schematic block diagram of a display device illustrated in FIG. 1.

FIG. 5A is a schematic diagram of an equivalent circuit of one of pixels illustrated in FIG. 4.

FIG. 5B is a schematic diagram of an equivalent circuit of one of pixels illustrated in FIG. 4.

FIG. 5C is a schematic diagram of an equivalent circuit of one of pixels illustrated in FIG. 4.

FIG. 6 is a schematic timing diagram of scan signals and a light emitting signal for describing the operation of a pixel illustrated in FIG. 5A.

FIG. 7 is a schematic cross-sectional view illustrating a partial region of a display panel.

FIGS. 8A and 8B are secondary ion mass spectroscopy (SIMS) graphs illustrating the change in content of hydrogen in a first channel region of a first transistor and a second channel region of a second transistor according to the disclosure.

FIGS. 9A to 9K are schematic cross-sectional views illustrating a method for manufacturing a display panel according to an embodiment of the disclosure.

FIG. 10 is a block diagram of an electronic device according to an embodiment of the disclosure.

FIG. 11 is a schematic view of various electronic devices according to embodiments of the disclosure.

### DETAILED DESCRIPTION OF THE EMBODIMENTS

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The same reference numeral will be assigned to the same component. The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first”, or “second” may be used to describe various components, the components should not be construed as being limited by the terms. The terms are only used to distinguish one component from another component. For example, without departing from the scope and spirit of the disclosure, a first component may be referred to as a second component, and similarly, the second component may be referred to as the first component. The singular forms are intended to include the plural forms unless the context clearly indicates otherwise.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The term “about” may include variations of, for example, +20%, +10%, or +5%, from the specified numerical value unless otherwise expressly stated. In some contexts, the term may account for rounding, inherent measurement limitations, or standard tolerances recognized in the relevant technical field. When applied to dimensions, concentrations, or other quantifiable parameters, “about” may include minor deviations that would be understood by a person of ordinary skill in the art as insubstantial in the given context. The scope of “about” should be interpreted in view of standard experimental or clinical tolerances applicable to the field of use. A person skilled in the art would recognize that “about” allows for practical deviations that do not materially alter the intended properties of the invention. Similarly, for mechanical dimensions, “about” may include deviations that are within industry-accepted tolerances and do not materially impact the performance of the disclosure.

It will be further understood that the terms “comprise,” “include,” or “including,” or “have” or “having” specify the presence of stated features, numbers, steps, operations, components, parts, or the combination thereof, but do not preclude the presence or addition of one or more other features, numbers, steps, operations, components, components, and/or the combination thereof.

Unless defined otherwise, all terms (including technical terms and scientific terms) used in the specification have the same meaning as commonly understood by one skilled in the art to which the disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

Hereinafter, embodiments of the disclosure will be described with reference to accompanying drawings.

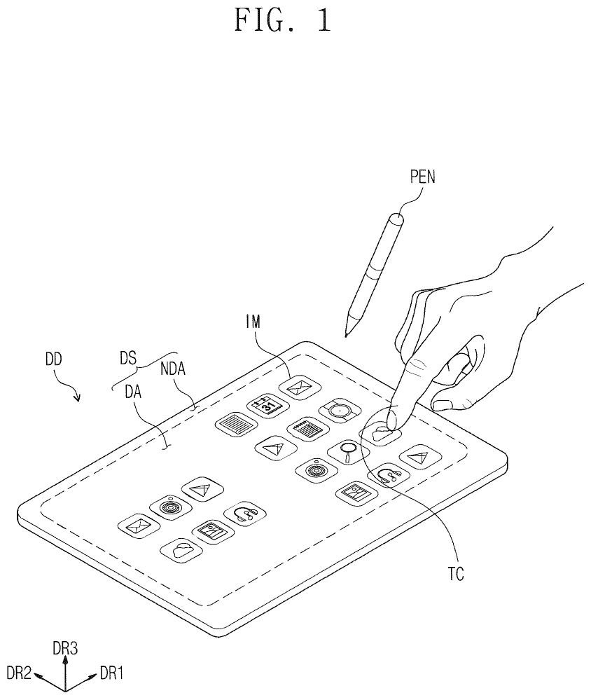

FIG. 1 is a perspective view of a display device DD according to an embodiment of the disclosure. As illustrated in FIG. 1, the display device DD may be in the shape of a rectangle having longer sides which extend in parallel to a first direction DR1 and shorter sides extending in a second direction DR2 intersecting the first direction DR1. However, the disclosure is not limited thereto. For example, the display device DD may have various shapes such as a circle or a polygon.

Hereinafter, a direction which is substantially perpendicular to a plane defined by the first direction DR1 and the second direction DR2 is defined as a third direction DR3. In this specification, the wording “in a plan view” may refer to the state when viewed in the third direction DR3. In other words, the wording “in a plan view” will be described based on a plan view defined by the first direction DR1 and the second direction DR2. In this specification, the wording “in a cross-sectional view” may indicate a state when viewed in the first direction DR1 or the second direction DR2. Directions indicated by the first direction DR1, the second direction DR2, and the third direction DR3 may be relative concepts and may be changed to different directions.

A front surface of the display device DD may be defined as a display surface DS and may be parallel to the plane defined by the first direction DR1 and the second direction DR2. Images IM generated from the display device DD may be provided to a user US through the display surface DS.

The display surface DS may include a display region DA and a non-display region NDA adjacent to the display region DA. The display region DA may be a region in which an image is displayed, and the non-display region NDA may be a region in which an image is not displayed. The non-display region NDA may be adjacent to at least one side of the display region DA. According to an embodiment, the non-display region NDA may have the form of a frame surrounding the display region DA.

The display device DD may sense inputs applied from an outside of the display device DD. For example, the display device DD may sense a first input by a touch pen PEN and a second input by a touch TC. The touch pen PEN may be an input device. The display region DA may provide, for a user, a sensing region for sensing an input in addition to displaying an image.

The touch pen PEN may be an active pen, or an electromagnetic pen. The second input by the touch TC may include various external inputs, such as a part of a physical body of a user, light, heat, or pressure. The touch pen PEN may be an active pen, a passive pen, or an electromagnetic pen, but the disclosure is not limited to any one embodiment.

The display device DD may be applied to a large-sized electronic item, such as a television set, a monitor, or an outdoor billboard. The display device DD may be applied to a small and medium-sized electronic item, such as a personal computer, a laptop computer, a personal digital assistant, a car navigation unit, a game unit, a smartphone, a tablet computer, or a camera. However, the disclosure is not limited thereto, and the display device DD may be employed in various forms.

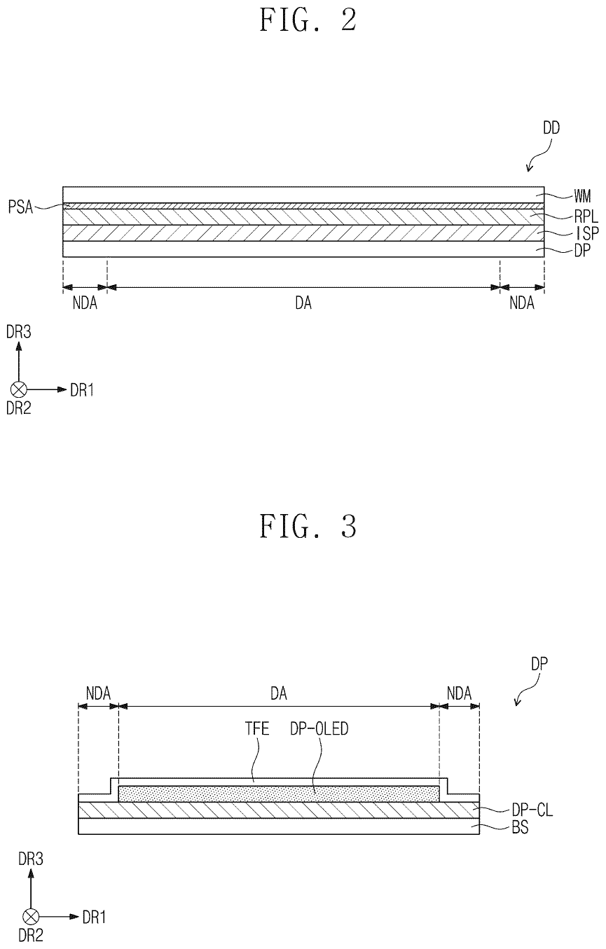

FIG. 2 is a schematic cross-sectional view illustrating the display device DD illustrated in FIG. 1. FIG. 3 is a schematic cross-sectional view illustrating a display panel DP illustrated in FIG. 2. The disclosure will be described with reference to FIGS. 2 and 3.

Referring to FIG. 2, the display device DD may include a display panel DP, an input sensing unit ISP, an anti-reflective layer RPL, an adhesive layer PSA, and a window WM.

The display panel DP according to an embodiment of the disclosure may be an emissive-type display panel, but the disclosure is not particularly limited thereto. For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot or a quantum rod. Hereinafter, the organic light emitting display panel as the display panel DP will be described.

The input sensing unit ISP may be directly disposed on the display panel DP. The input sensing unit ISP may sense a user input using, for example, an electromagnetic induction manner and/or a capacitive manner. The input sensing unit ISP may be directly disposed on the display panel DP. Herein, the expression “being directly disposed” may refer to that a third component is not intervened between the input sensing unit ISP and the display panel DP, and an additional adhesive layer may not be interposed between the input sensing unit ISP and the display panel DP. The display panel DP and the input sensing unit ISP may be formed through subsequent processes.

In an embodiment, a conductive pattern or an insulating layer constituting the input sensing unit ISP may be directly deposited or patterned on the display panel DP. However, the disclosure is not limited thereto. For example, the input sensing unit ISP may be manufactured in the form of a panel separate from the display panel DP, and may be bonded to the display panel DP by an adhesive layer.

The anti-reflective layer RPL may be disposed on the input sensing unit ISP. The anti-reflective layer RPL may decrease the reflectance of an external light incident on the display device DD to improve the visibility of an image displayed on the display device DD. The anti-reflective layer RPL may include a phase retarder, a polarizer, a black matrix, or a color filter, but the disclosure is not limited to any one embodiment. The anti-reflective layer RPL may be directly formed on the input sensing unit ISP through a coating process or a deposition process, or may be provided in the form of a film and bonded to the input sensing unit ISP by an adhesive layer, but the disclosure is not limited thereto.

The adhesive layer PSA may be interposed between the anti-reflective layer RPL and the window WM, and the anti-reflective layer RPL and the window WM may be bonded to each other by the adhesive layer PSA. However, the disclosure is not limited thereto. According to another embodiment, the adhesive layer PSA may be omitted.

The window WM may be disposed on the anti-reflective layer RPL. The window WM may protect the display panel DP, the input sensing unit ISP, and the anti-reflective layer RPL from an external scratch and an external impact. According to an embodiment, the window WM may be formed through a coating. The window WM may be directly disposed on the display panel DP.

Referring to FIG. 3, the display panel DP may include a base layer BS, a circuit element layer DP-CL on the base layer BS, a display element layer DP-OLED on the circuit element layer DP-CL, and a thin film encapsulating layer TFE on the display element layer DP-OLED.

The base layer BS may include a display region DA and a non-display region NDA adjacent to the display region DA. The base layer BS may include a glass substrate, a metal substrate, a polymer substrate, or an organic/inorganic composite substrate.

The circuit element layer DP-CL and the display element layer DP-OLED may be disposed on the base layer BS. Multiple pixels may be disposed in the circuit element layer DP-CL and the display element layer DP-OLED. Each of the pixels may include a transistor in the circuit element layer DP-CL and a light emitting element in the display element layer DP-OLED and connected to the transistor.

The thin film encapsulating layer TFE may be disposed on the circuit element layer DP-CL and cover the display element layer DP-OLED. The thin film encapsulating layer TFE may protect the pixels from moisture, oxygen, and external foreign substances. According to an embodiment, although the thin film encapsulating layer TFE covers a whole region of the base layer BS, the base layer BS may include a partial region exposed from the thin film encapsulating layer TFE. In another embodiment, the region exposed from the thin film encapsulating layer TFE may be formed along the edge of the base layer BS, but the disclosure is not limited any one embodiment.

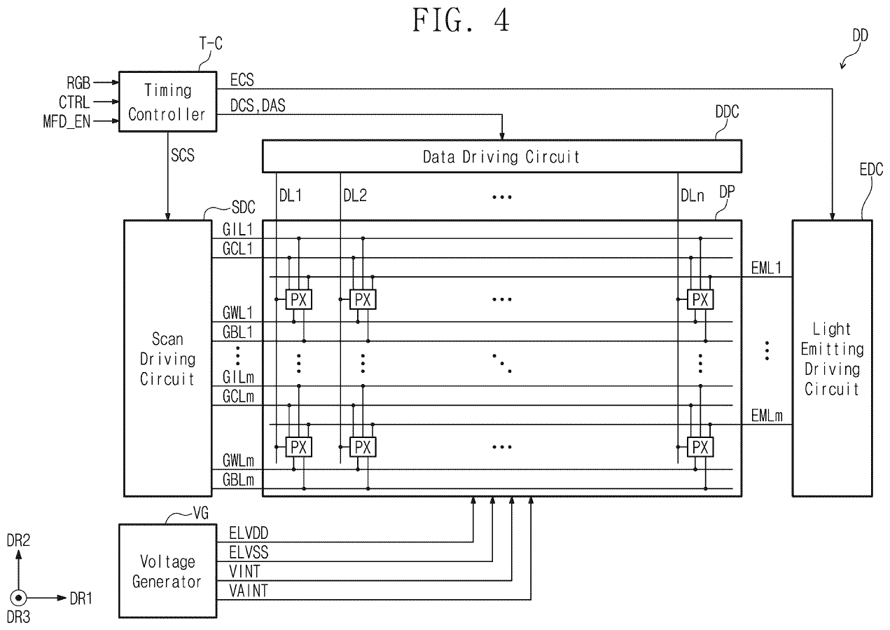

FIG. 4 is a schematic block diagram of the display device DD according to an embodiment of the disclosure. The display device DD may include a display panel DP, a timing controller T-C, a scan driving circuit SDC, a data driving circuit DDC, a light emitting driving circuit EDC, and a voltage generator VG.

The display panel DP may include multiple scan lines GIL1 to GILm, GCL1 to GCLm, GWL1 to GWLm, and GBL1 to GBLm, multiple light emitting lines EML1 to EMLm, multiple data lines DL1 to DLn, and multiple pixels PX. ‘m’ and ‘n’ may be natural numbers.

The pixels PX may be electrically connected to the scan lines GIL1 to GILm, GCL1 to GCLm, GWL1 to GWLm, and GBL1 to GBLm, the light emitting lines EML1 to EMLm, and the data lines DL1 to DLn. Each of the pixels PX may be electrically connected to four corresponding scan lines, one corresponding data signal line, and one corresponding light emitting signal line.

The scan lines GIL1 to GILm, GCL1 to GCLm, GWL1 to GWLm, and GBL1 to GBLm may include multiple initializing scan lines GIL1 to GILm, multiple compensating scan lines GCL1 to GCLm, multiple write scan lines GWL1 to GWLm, and multiple bias scan lines GBL1 to GBLm.

Each pixel PX may be connected to one of the initializing scan lines GIL1 to GILm, one of the compensating scan lines GCL1 to GCLm, one of the write scan lines GWL1 to GWLm, and one of the bias scan lines GBL1 to GBLm.

The scan lines GIL1 to GILm, GCL1 to GCLm, GWL1 to GWLm, and GBL1 to GBLm may be connected to the scan driving circuit SDC and may be arranged in the second direction DR2 while extending in the first direction DR1. The light emitting lines EML1 to EMLm may be connected to the light driving circuit EDC and may be arranged in the second direction DR2 while extending in the first direction DR1. The data lines DL1 to DLn may be connected to the data driving circuit DDC and may be arranged in the first direction DR1 while extending in the second direction DR2.

According to an embodiment, the scan driving circuit SDC, the light emitting driving circuit EDC, and the data driving circuit DDC may be substantially disposed in the display panel DP. However, the disclosure is not limited thereto. For example, at least one of the scan driving circuit SDC, the light emitting driving circuit EDC, and the data driving circuit DDC may be provided in an additional circuit board and electrically connected to the display panel DP, and an electrical signal may be applied to the pixels PX. However, the disclosure is not limited to any one embodiment.

The timing controller T-C may receive an image signal RGB and a control signal CTRL. The timing controller T-C may generate image data signal DAS obtained by transforming the data format of the image signal RGB to be matched with the interface specification of the data driving circuit DDC. The timing controller T-C may output a scan control signal SCS, a data control signal DCS, and a light emitting control signal ECS, in response to the control signal CTRL.

The scan driving circuit SDC may receive the scan control signal SCS from the timing controller T-C. The scan control signal SCS may include a vertical start signal for starting an operation of the scan driving circuit SDC and a clock signal for determining output timing of the signals.

The scan driving circuit SDC may generate the scan signals in response to the scan control signal SCS, and may output the scan signals to the scan lines GIL1 to GILIm, GCL1 to GCLm, GWL1 to GWLm, and GBL1 to GBLm. The scan signals may be applied to the pixels PX through the scan lines GIL1 to GILIm, GCL1 to GCLm, GWL1 to GWLm, and GBL1 to GBLm.

The data driving circuit DDC may receive the data control signal DCS and the image data signal DAS from the timing controller T-C. The data driving circuit DDC may transform the image data signal DAS into data signals and output the data signals. The data signals may be defined as analog voltages corresponding to grayscale levels of the image data signal DAS. The data signals may be applied to the pixels PX through the data lines DL1 to DLn.

The light emitting driving circuit EDC may receive the light emitting control signal ECS from the timing controller T-C. The light emitting driving circuit EDC may output light emitting signals to the light emitting lines EML1 to EMLm in response to the light emitting control signal ECS. The light emitting signals may be applied to the pixels PX through the light emitting lines EML1 to DLn.

The pixels PX may receive the data voltages in response to the scan signals. The pixels PX may display an image by emitting a light of brightness corresponding to data voltages in response to the light emitting signals.

The voltage generator VG may generate voltages for an operation of the display panel DP. The voltage generator VG may generate a first driving voltage ELVDD, a second driving voltage ELVSS, a first initializing voltage VINT, and a second initializing voltage VAINT. The first driving voltage ELVDD, the second driving voltage ELVSS, the first initializing voltage VINT, and the second initializing voltage VAINT may be applied to the pixels PX.

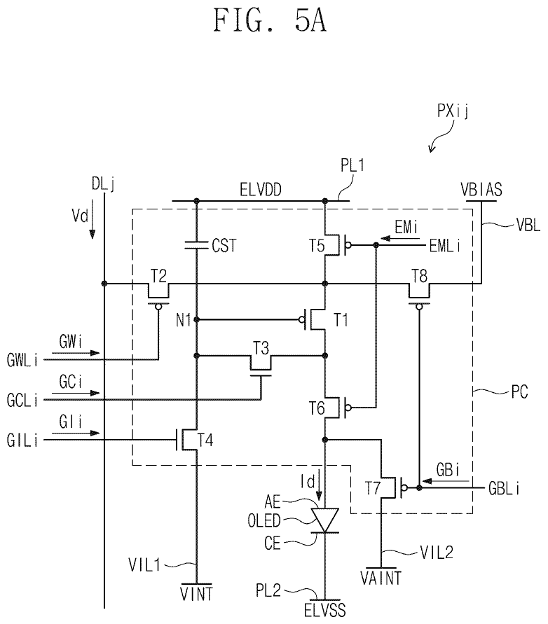

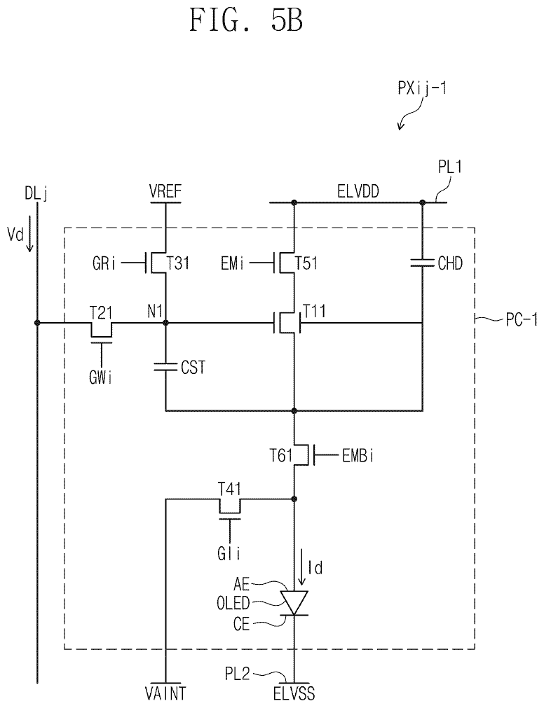

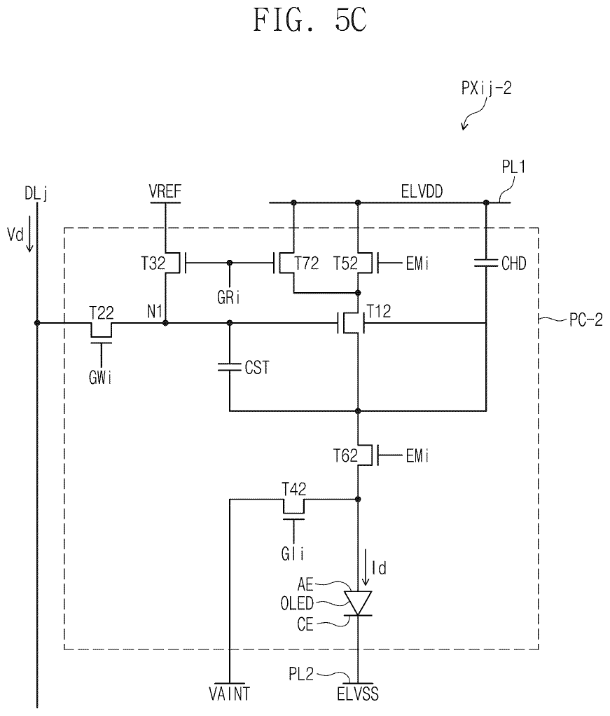

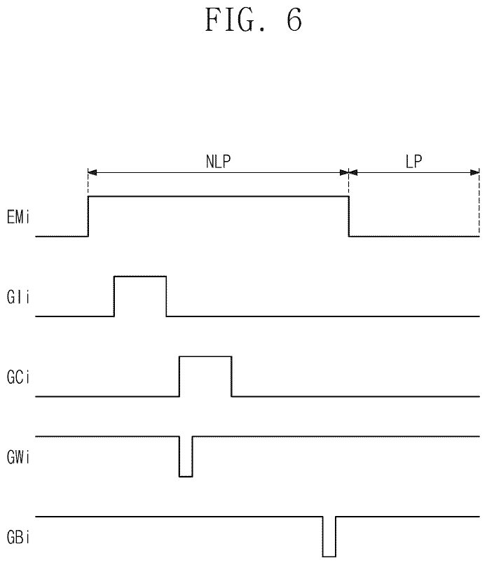

FIGS. 5A to 5C are schematic diagrams of equivalent circuits of one of the pixels PX illustrated in FIG. 4. FIG. 6 is a schematic timing diagram of scan signals and a light emitting signal for describing the operation of a pixel according to an embodiment of the disclosure. FIG. 6 is a schematic timing diagram of a pixel of FIG. 5A for the convenience of explanation. Hereinafter, a pixel will be described in more detail with reference to FIGS. 5A to 6.

For example, FIG. 5A schematically illustrates a pixel PXij connected to the j-th data line DLj, the i-th scan lines GWLi, GCLi, GILi, and GBLi, and the i-th light emitting line EMLi. “i” and “j” may be natural numbers.

Referring to FIG. 5A, the pixel PXij may include a pixel driving circuit PC and a light emitting element OLED connected to the pixel driving circuit PC. The pixel driving circuit PC may drive the light emitting element OLED.

The pixel driving circuit PC may include multiple transistors T1 to T8 and a capacitor CST. The transistors T1 to T8 and the capacitor CST may control an amount of current flowing through the light emitting element OLED. The light emitting element OLED may generate a light having a brightness, based on an amount of current provided.

The i-th write scan line GWLi may receive an i-th write scan signal GWi, and the i-th compensating scan line GCLi may receive an i-th compensating scan signal GCi. The i-th initializing scan line GILi may receive an i-th initializing scan signal GIi, and the i-th bias scan line GBLi may receive an i-th bias scan signal GBi. The i-th light emitting line EMLi may receive an i-th light emitting signal EMi.

The pixel PXij may be connected to the j-th data line DLj, the i-th write scan line GWLi, the i-th compensating scan line GCLi, the i-th initializing scan line GILi, the i-th bias scan line GBLi, the i-th light emitting line EMLi, a first initializing line VIL1, a second initializing line VIL2, a bias line VBL, and first and second power supply lines PL1 and PL2.

The first initializing line VIL1 may receive the first initializing voltage VINT, the second initializing line VIL2 may receive the second initializing voltage VAINT. The bias line VBL may receive the bias voltage VBIAS. The first power supply line PL1 may receive the first driving voltage ELVDD, and the second power supply line PL2 may receive the second driving voltage ELVSS.

Each of the first to eighth transistors T1 to T8 may include a source electrode, a drain electrode, and a gate electrode. Hereinafter, one of the source electrode and the drain electrode will be defined as a first electrode, and a remaining one of the source electrode and the drain electrode will be defined as a second electrode for the convenience of explanation, when referring to FIGS. 5A to 5C. The gate electrode may be defined as a control electrode.

The transistors T1 to T8 may include first to eighth transistors T1 to T8. The first, second, and fifth to eighth transistors T1, T2, and T5 to T8 may be PMOS transistors. The third and fourth transistors T3 and T4 may be an NMOS transistors.

The first transistor T1 may be a driving transistor, and the second transistor T2 may be a switching transistor. The third transistor T3 may be a compensating transistor. The fourth transistor T4 and the seventh transistor T7 may be initializing transistors. The fifth transistor T5 and the sixth transistor T6 may be light emitting control transistors. The third transistor T8 may be a bias transistor.

The light emitting element OLED may be an organic light emitting element. The light emitting element OLED may include an anode AE and a cathode CE. The anode AE may receive the first driving voltage ELVDD through the sixth, first, and fifth transistors T6, T1, and T5. The first driving voltage ELVDD may be applied to the pixel driving circuit PC through the first power supply line PL1.

The cathode CE may receive the second driving voltage ELVSS having a level lower than the first driving voltage ELVDD. The second driving voltage ELVSS may be applied to the pixel driving circuit PC through the second power supply line PL2.

The first transistor T1 may be interposed between the fifth transistor T5 and the sixth transistor T6 and connected to the fifth transistor T5 and the sixth transistor T6. The first transistor T1 may be connected to the first power supply line PL1 through the fifth transistor T5, and may be connected to an anode AE through the sixth transistor T6.

The first transistor T1 may include a first electrode connected to the first power supply line PL1 through the fifth transistor T5, a second electrode connected to the anode AE through the sixth transistor T6, and a control electrode connected to a first node N1.

The first electrode of the first transistor T1 may be connected to the fifth transistor T5, and the second electrode of the first transistor T1 may be connected to the sixth transistor T6. The first transistor T1 may control an amount of current flowing through the light emitting element OLED depending on the voltage at the first node N1, which is applied to the control electrode of the first transistor T1.

The second transistor T2 may be interposed between the first transistor T1 and the j-th data line DLj and may be connected to the first transistor T1 and the j-th data line DLj. The second transistor T2 may include a first electrode connected to the j-th data line DLj, a second electrode connected to the first electrode of the first transistor T1, and a control electrode connected to the i-th write scan line GWLi.

The second transistor T2 may be turned on in response to the i-th write scan signal GWi applied through the i-th write scan line GWLi to electrically connect the j-th data line DLj to the first electrode of the first transistor T1. The second transistor T2 may perform a switching operation for supplying a data voltage Vd, which is received through the j-th data line DLj, to the first electrode of the first transistor T1.

The third transistor T3 may be connected between the second electrode of the first transistor T1 and the first node N1. The third transistor T3 may include a first electrode connected to the second electrode of the first transistor T1, a second electrode connected to the first node N1, and a control electrode connected to the i-th compensating scan line GCLi.

The third transistor T3 may be turned on in response to the i-th compensating scan signal GCi, which is received through the i-th compensating scan line GCLi, to electrically connect the second electrode of the first transistor T1 to the control electrode of the first transistor T1. In case that the third transistor T3 is turned on, the first transistor T1 and the third transistor T3 may be connected in the form of diodes.

The fourth transistor T4 may be connected to the first node N1. The fourth transistor T4 may include a first electrode connected to the first node N1, a second electrode connected to the first initializing line VIL1, and a control electrode connected to the i-th initializing scan line GILi. The fourth transistor T4 may be turned on in response to the i-th initializing scan signal GIi, which is received through the i-th initializing scan line GCLi, to provide the first initializing voltage VINT, which is received through the first initializing line VIL1, to the first node N1.

The fifth transistor T5 may include a first electrode connected to the first power supply line PL1, a second electrode connected to the first electrode of the first transistor T1, and a control electrode connected to the i-th light emitting line EMLi.

The sixth transistor T6 may include a first electrode connected to the second electrode of the first transistor T1, a second electrode connected to the anode AE, and a control electrode connected to the i-th light emitting line EMLi.

The fifth transistor T5 and the sixth transistor T6 may be turned on in response to the i-th light emitting signal EMi received through the i-th light emitting line EMLi. The first voltage ELVDD may be provided to the light emitting element OLED in response to the fifth transistor T5 and the sixth transistor T6, which are turned on, such that a driving current may flow through the light emitting element OLED. Accordingly, the light emitting element OLED may emit a light.

The seventh transistor T7 may include a first electrode connected to the anode AE, a second electrode connected to the second initializing line VIL2, and a control electrode connected to the i-th bias scan line GBLi. The seventh transistor T7 may be turned on in response to the i-th bias scan signal GBi, which is received through the i-th bias scan line GBLi, to provide the second initializing voltage VAINT, which is received through the second initializing line VIL2, to the anode electrode AE of the light emitting element OLED.

According to an embodiment of the disclosure, a level of the second initializing voltage VAINT and a level of the first initializing voltage VINT may be different from each other, but the disclosure is not limited thereto. In another embodiment, the second initializing voltage VAINT and the first initialization voltage VINT may have a same level.

The seventh transistor T7 may improve the black expression ability of the pixel PXij. In case that the seventh transistor T7 is turned on, a parasitic capacitor (not shown) of the light emitting element OLED may be discharged. Accordingly, when implementing black brightness, the light emitting element OLED may not emit light due to the leakage current of the first transistor T1. Accordingly, the black expression ability may be improved.

The capacitor CST may include a first electrode connected to the first power supply line PL1 and a second electrode connected to the first node N1. In case that the fifth transistor T5 and the sixth transistor T6 are turned on, the amount of current flowing through the first transistor T1 may be determined based on the voltage stored in the capacitor CST.

The eighth transistor T8 may include a first electrode connected to the bias line VBL, a second electrode connected to the first electrode of the first transistor T1, and a control electrode connected to the i-the bias scan line GBLi.

The eighth transistor T8 may be turned on in response to the i-th bias scan signal GBi, and may provide a bias voltage VBIAS, which is received through the bias line VBL, to the first electrode of the first transistor T1.

Referring to FIGS. 5A and 6, the i-th light emitting signal EMi may have a high level during a non-light emitting period NLP, and may have a low level during a light emitting period LP.

In case that each of the i-th write scan signal GWi and the i-th bias scan signal GBi are in a low level, the i-th write scan signal GWi and the i-th bias scan signal GBi may be defined as being activated.

In case that each of the i-th compensating scan signal GCi and the i-th initializing scan signal GIi are in a high level, the i-th compensating scan signal GCi and the i-th initializing scan signal GIi may be defined as being activated.

After the i-th initializing scan signal GIi is activated, the i-th compensating scan signal GCi and the i-th write scan signal GWi may be activated. Thereafter, the i-th bias scan signal GBi may be activated.

During the non-light emitting period NLP, the i-th initializing scan signal GIi, the i-th compensating scan signal GCi, the i-th write scan signal GWi, and the i-th bias scan signal GBi, which are activated, may be applied to the pixel PXij.

As the i-th initializing scan signal GIi is applied to the fourth transistor T4, the fourth transistor T4 may be turned on. The first initializing voltage VINT may be provided to the node N1 through the fourth transistor T4. Accordingly, the first initializing voltage VINT may be applied to the control electrode of the first transistor T1, and the first transistor T1 may be initialized in response to the first initializing voltage VINT. Such an operation may be defined as an initializing operation.

As the i-th write scan signal GWi is applied to the second transistor T2, the second transistor T2 may be turned on. As the i-th compensating scan signal GCi is applied to the third transistor T3, the third transistor T3 may be turned on.

The first transistor T1 and the third transistor T3 may be connected to each other in the form of a diode, and a compensation voltage “Vd-Vth” obtained by subtracting a threshold voltage Vth of the first transistor T1 from a data voltage Vd received through the data line DLj may be applied to the gate electrode of the first transistor T1. Such operations may be defined as a write operation and a compensation operation.

The first driving voltage ELVDD and the compensation voltage “Vd-Vth” may be applied to the first electrode and the second electrode of the capacitor CST. The capacitor CST may store charges corresponding to the difference between a voltage of the first electrode of the capacitor CST and a voltage of the second electrode of the capacitor CST.

Thereafter, as the i-th bias scan signal GBi is applied to the seventh and eighth transistors T7 and T8, the seventh and eighth transistors T7 and T8 may be turned on. As the second initializing voltage VAINT is applied to the anode AE through the seventh transistor T7, the anode AE may be initialized to the second initializing voltage VAINT. The bias voltage VBIAS may be applied to the first electrode of the first transistor T1 through the eighth transistor T8.

Thereafter, as the i-th light emitting signal EMi is applied to the fifth transistor T5 and the sixth transistor T6 through the i-th light emitting line EMLi during the light emitting period LP, the fifth transistor T5 and the sixth transistor T6 may be turned on. A driving current Id may be generated corresponding to the difference between the voltage of the control electrode of the first transistor T1 and the first driving voltage ELVDD. As the driving current Id is applied to the light emitting element OLED through the sixth transistor T6, the light emitting element OLED may emit a light.

The gate-source voltage Vgs of the first transistor T1 may be defined as “Vgs=ELVDD−(Vd−Vth)” by the capacitor CST during the light emitting period LP. The relationship between a current and a voltage of the first transistor T1 may be defined as

$$Id = ( \frac{1}{2} ) μ Cox ( \frac{W}{L} ) {( Vgs - Vth )}^{2} .$$

Such a relationship is a typical relationship between a current and a voltage of a transistor.

In case that a gate-source voltage Vgs is substituted into the relationship between the current and the voltage, the threshold voltage Vth may be removed, and the driving current Id may be proportional to a square root ((E̅L̅V̅D̅D̅−̅V̅d̅)²) of a value obtained by subtracting a data voltage Vd from the first driving voltage ELVDD. Accordingly, the driving current Id may be determined regardless of the threshold voltage Vth of the first transistor T1. Such an operation may be defined as a threshold voltage compensating operation.

The bias voltage VBIAS may be applied to the first electrode of the first transistor T1 through the eighth transistor T8 before the light emitting element OLED emits a light after the threshold voltage of the first transistor T1 is compensated. The shift of the hysteresis curve of the first transistor T1 may be suppressed by the bias voltage VBIAS. Such an operation may be defined as a bias operation.

Referring to FIG. 5B, the pixel PXij-1 may include a pixel driving circuit PC-1 and a light emitting element OLED connected to the pixel driving circuit PC-1. The pixel driving circuit PC-1 may include six transistors T11, T21, T31, T41, T51, and T61, and two capacitors CST and CHD.

The first transistor T11 may be a driving transistor, and the second transistor T21 may be a switching transistor.

The third transistor T31 may be a reset transistor. The third transistor T31 may provide a reference voltage VREF to a first node N1, in response to a reset signal GRi received from the scan driving circuit SDC (see FIG. 4). The first node N1 may be reset to the reference voltage VREF to minimize an influence by a voltage remaining in a previous stage.

The fourth transistor T41 may be an anode initializing transistor. The fourth transistor T41 may correspond to the seventh transistor T7 (see FIG. 5A) illustrated in FIG. 5A. The fourth transistor T41 may initialize the anode of the light emitting element OLED with the second initializing voltage VAINT, in response to the i-th initializing scan signal GIi.

The fifth transistor T51 and the sixth transistor T61 may be light emitting control transistors. According to an embodiment, the fifth transistor T51 and the sixth transistor T61 may be driven by different light emitting control signals. For example, the fifth transistor T51 may transmit the first driving voltage ELVDD to the first transistor T11, in response to a first light emitting signal EMi, and the sixth transistor T61 may be turned on in response to a second light emitting signal EMBi. According to an embodiment, the fifth transistor T51 and the sixth transistor T61 may be turned on or turned off at different timings to be driven independently from each other. According to an embodiment, the first light emitting signal EMi may correspond to the i-th light emitting signal EMi, and the second light emitting signal EMBi may be a signal independent from the first light emitting signal EMi. However, the disclosure is not limited thereto. In another embodiment, the first light emitting signal EMi and the second light emitting signal EMBi may be applied at a same timing.

Referring to FIG. 5C, the pixel PXij-2 may include a pixel driving circuit PC-2 and a light emitting element OLED connected to the pixel driving circuit PC-2. The pixel driving circuit PC-2 may include seven transistors T12, T22, T32, T42, T52, T62, and T72, and two capacitors CST and CHD. The first transistor T12 may be a driving transistor, and the second transistor T22 may be a switching transistor. The third transistor T32 may be a reset transistor, and the fourth transistor T42 may be an anode initializing transistor. The fifth transistor T52 and the sixth transistor T62 may be light emitting control transistors.

Compared to embodiments of FIG. 5B, the pixel driving circuit PC-2 may further include the seventh transistor T72. The seventh transistor T72 may be interposed between the first driving voltage ELVDD and a drain of the first transistor T12. The seventh transistor T72 may provide the first driving voltage ELVDD to the first transistor T12, in response to the reset signal GRi, and the seventh transistor T72 and the third transistor T32 may be simultaneously turned on at a same timing. In other words, the drain of the first transistor T12 may receive the first driving voltage ELVDD at the timing at which the first node N1 is reset.

The sixth transistor T62 may be driven in response to the i-th light emitting signal EMi. In other words, the sixth transistor T62 and the fifth transistor T52 may be simultaneously turned on at a same timing.

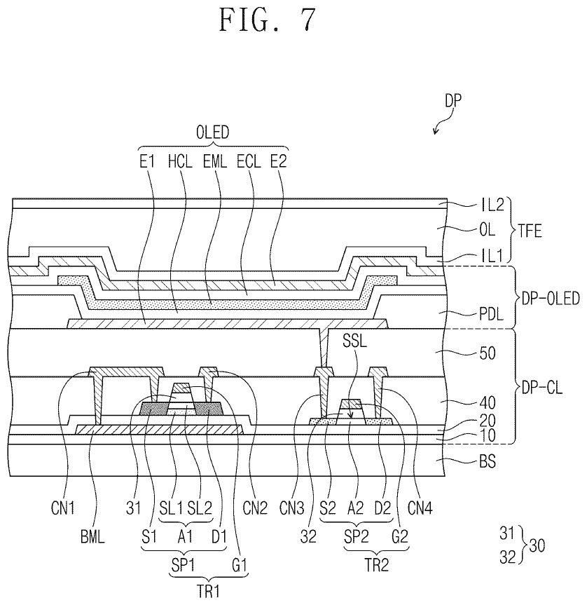

FIG. 7 is a schematic cross-sectional view illustrating a partial region of the display panel DP. FIG. 7 schematically illustrates a region in which two transistors TR1 and TR2 of components of each pixel PXij and the light emitting element OLED are disposed. Referring to FIG. 7, the display panel DP may include a base layer BS, a circuit element layer DP-CL, a display element layer DP-OLED, and an encapsulating layer TFE.

According to an embodiment, the base layer BS may include at least one synthetic resin layer. The synthetic resin layer included in the base layer BS may include at least one of an acrylic resin, a methacrylic resin, a polyisoprene, a vinyl-based resin, an epoxy-based resin, a urethane-based resin, a cellulose-based resin, a siloxane-based resin, a polyamide-based resin, a polyimide-based resin, and a perylene resin.

The base layer BS may have a single-layer or a multi-layer structure. For example, the base layer BS may include a stack structure of multiple plastic films bonded by an adhesive or may have a stack structure of a glass substrate and a plastic film bonded by an adhesive.

According to an embodiment, the base layer BS may be a flexible substrate. In case that the base layer BS is a flexible substrate, the base layer BS may be bendable, foldable, or rollable. However, the disclosure is not limited thereto. In another embodiment, the base layer BS may be provided in a rigid state, and may not be limited to any one embodiment.

The circuit element layer DP-CL may be disposed on the base layer BS. The circuit element layer DP-CL may include a circuit element and multiple insulating layers 10, 20, 30, 40, and 50. The two transistors T1 and T2 described below may be elements that constitute the circuit element layer DP-CL. Although FIG. 7 illustrates that the insulating layers 10, 20, 30, 40, and 50 include the first to fifth insulating layers 10, 20, 30, 40, and 50 sequentially stacked on the base layer BS, the disclosure is not limited thereto. The number of insulating layers constituting the circuit element layer DP-CL may be variously changed, and the disclosure is not limited to any one embodiment.

Two transistors TR1 and TR2 may be disposed on the base layer BS. The two transistors TR1 and TR2 may include a first transistor TR1 and a second transistor TR2. According to an embodiment, the first insulating layer 10 and the second insulating layer 20 may be interposed between the two transistors TR1 and TR2 and the base layer BS. According to an embodiment, the first transistor TR1 may be the driving transistor T1, T11, or T12 illustrated in FIGS. 5A to 5C, and the second transistor TR2 may be the switching transistor T2, T21, or T22 illustrated in FIGS. 5A to 5C.

The first insulating layer 10 may be disposed on the base layer BS and entirely cover a top surface of the base layer BS. The first insulating layer 10 may include a barrier layer. In other words, the first insulating layer 10 may prevent oxygen or moisture, which may be introduced through the base layer BS, from being introduced into the pixel PXij.

A lower metal layer BML may be further interposed between the first transistor TR1 and the base layer BS. The lower metal layer BML may be a light blocking pattern, and may include a black matrix, or a reflective conductive material. For example, the lower metal layer BML may include a metal material, and may overlap the first transistor TR1 in a plan view to protect a semiconductor pattern of the first transistor TR1. The lower metal layer BML may be disposed under the first transistor TR1 to prevent electrical potential to exert an influence on the transistor T1 or to prevent an external light from reaching the transistor.

According to an embodiment, the lower metal layer BML may be connected to an electrode or a wire to receive a constant voltage. According to an embodiment, the lower metal layer BML may be a floating electrode that is isolated from another electrode or line.

The second insulating layer 20 may be disposed on the first insulating layer 10 and cover the lower metal layer BML The second insulating layer 20 may entirely cover the base layer BS. The second insulating layer 20 may include a buffer layer. The buffer layer may include at least one of an aluminum oxide, a titanium oxide, a silicon oxide, a silicon nitride, a silicon oxynitride, a zirconium oxide, and a hafnium oxide.

In other words, the second insulating layer 20 may reduce surface energy of a surface for forming the circuit element layer DP-CL such that the pixels PXij is stably formed on the base layer BS. At least one of the barrier layer and the buffer layer may include multiple layers, or may be omitted. In the display panel according to an embodiment of the disclosure, the first insulating layer 10 and/or the second insulating layer 20 may be omitted, and the disclosure is not limited to any one embodiment.

The first transistor TR1 and the second transistor TR2 may be disposed on the second insulating layer 20. The first transistor TR1 may include a first oxide semiconductor pattern SP1 and a first gate G1. The first transistor TR1 may be a driving transistor on a current path between the first power supply line PL1 and the light emitting element OLED to control an amount of current flowing through the light emitting element OLED, but the disclosure is not limited thereto. The first oxide semiconductor pattern SP1 may include a first source region S1, a first drain region D1, and a first channel region A1.

The first oxide semiconductor pattern SP1 may include multiple regions having different electrical properties. The first oxide semiconductor pattern SP1 may include multiple regions divided depending on whether the metal oxide is reduced. For example, the first oxide semiconductor pattern SP1 may include the first source region S1, the first drain region D1, and the first channel region A1 divided depending on conductivity. For example, the first channel region A1 may be a region having lower conductivity than the first source region S1 and the first drain region D1, and may be a region having a semiconductor property. The first source region S1 and the first drain region D1 may be regions having higher conductivity than the first channel region A1. The first channel region A1 may be referred to as the first active region A1. For the convenience of explanation, the first oxide semiconductor pattern SP1 may be referred to as a semiconductor pattern, and each of the first source region S1 or the first drain region D1 may be referred to as a source or a drain.

Each of the first source region S1 and the first drain region D1 may be formed through doping or reduction. For example, in the semiconductor pattern, a heavily-doped region having a higher dopant concentration may have higher conductivity. A partial region of the semiconductor pattern may be doped to be a source/drain, and a remaining region may be channel. The dopant may be a P-type dopant or an N-type dopant, and the disclosure is not limited to any one embodiment.

A reduced region of the semiconductor pattern may have higher conductivity as compared to the conductivity of a region not reduced. Since the metal oxide constituting the semiconductor pattern is deposited as a metal through a reduction process, a region in which the metal oxide may be reduced may be a source/drain and a remaining region may be a channel region.

According to an embodiment, the first source region S1 and the first drain region D1 may be formed from the first oxide semiconductor pattern SP1. However, the disclosure is not limited thereto. In another embodiment, the source and the drain of the first transistor TR1 may be provided through an additional conductive pattern connected to the first oxide semiconductor pattern SP1, and the disclosure is not limited to any one embodiment.

According to an embodiment, the first channel region A1 of the first oxide semiconductor pattern SP1 may have a multi-layer structure. For example, the first channel region A1 may include a first oxide semiconductor layer SL1 and a second oxide semiconductor layer SL2 on the first oxide semiconductor layer SL1.

The first oxide semiconductor layer SL1 and the second oxide semiconductor layer SL2 may include different metal oxide semiconductor materials. For example, the first oxide semiconductor layer SL1 may include an oxide of a metal, such as zinc (Zn), indium (In), gallium (Ga), titanium (Ti), or a mixture thereof.

According to an embodiment, the first oxide semiconductor layer SL1 may include an indium-gallium-zinc oxide (IGZO), a zinc oxide (ZnO), an indium-zinc oxide (IZnO), a zinc-indium oxide (ZIO), an indium oxide (InO), or a titanium oxide (TiO).

The second oxide semiconductor layer SL2 may include an oxide of a metal, such as zinc (Zn), indium (In), gallium (Ga), tin (Sn), titanium (Ti), or a mixture thereof.

According to an embodiment, the second oxide semiconductor layer SL2 may include indium-tin oxide (ITO), indium-zinc-tin oxide (IZTO), zinc-tin oxide (ZTO), or indium-tin-gallium-zinc oxide (ITGZO). In the indium-tin-gallium-zinc oxide (ITGZO) of the second oxide semiconductor layer SL2, the indium may have a composition ratio in a range of about 60 wt % to about 80 wt %, the tin may have a composition ratio in a range of about 0.5 wt % to about 8 wt %, the gallium may have a composition ratio in a range of about 5 wt % to about 15 wt %, and the zinc may have a composition ratio in a range of about 10 wt % to about 30 wt %, but the disclosure is not limited thereto. As long as the second oxide semiconductor layer SL2 has higher mobility, the second oxide semiconductor layer SL2 may include an oxide having various compositions, and the disclosure is not limited to any one embodiment.

The first gate G1 may be disposed on a semiconductor pattern of the first transistor TR1. The first gate G1 may overlap the first channel region A1 in a plan view. The first insulating pattern 31 may be interposed between the first gate G1 and the semiconductor pattern. The first insulating pattern 31 may be patterned in the shape aligned with the first gate G1. The first insulating pattern 31 may be a gate insulating layer, and the first transistor TR1 may have a top-gate structure. However, the disclosure is not limited thereto. The first insulating pattern 31 may be provided in a layer having an integral shape to cover the whole region of the base layer BS, and the first transistor TR1 may have a bottom-gate structure, but the disclosure is not limited thereto.

The second transistor TR2 may include a second oxide semiconductor pattern SP2 and a second gate G2. The second transistor TR2 may be a switching transistor for applying a data voltage to the first transistor TR1 in response to a scan signal applied to a scan line, but the disclosure is not limited thereto. The second oxide semiconductor pattern SP2 may include a second source region S2, a second drain region D2, and a second channel region A2.

According to an embodiment, the second channel region A2 of the second oxide semiconductor pattern SP2 may have a single-layer structure. For example, the second channel region A2 may include an oxide semiconductor layer SSL in a single layer.

According to an embodiment, the second oxide semiconductor pattern SP2 and the second oxide semiconductor layer SL2 of the first oxide semiconductor pattern SP1 may be formed through a same process. Accordingly, an oxide semiconductor layer SSL of the second oxide semiconductor pattern SP2, which is in a single layer, and the second oxide semiconductor layer SL2 may include a same material. For example, the oxide semiconductor layer SSL of the second oxide semiconductor pattern SP2, which is in a single layer, may include an indium-tin-gallium-zinc oxide (ITGZO), and may have a composition ratio same as the composition ratio of the second oxide semiconductor layer SL2. The details of components, which perform the same functions as those of the first oxide semiconductor pattern SP1, of the second oxide semiconductor pattern SP2 may be omitted to avoid redundancy.

The second gate G2 may be spaced apart from the second oxide semiconductor pattern SP2 while interposing the second insulating pattern 32 between the second gate G2 and the second oxide semiconductor pattern SP2, and may be disposed on the second oxide semiconductor pattern SP2. The second gate G2 may overlap the second channel region A2 in a plan view. Although the second transistor TR2 is illustrated in a top-gate structure, which is similar to the first transistor TR1, the disclosure is not limited thereto, and in another embodiment, the second transistor TR2 may have a bottom-gate structure.

According to an embodiment, the thickness of the first oxide semiconductor pattern SP1 may be greater than the thickness of the second oxide semiconductor pattern SP2. For example, the thickness of the first oxide semiconductor pattern SP1 may be greater than or equal to about 250 Å. In case that the thickness of the first oxide semiconductor pattern SP1 is less than a specific range, an edge part of the first oxide semiconductor pattern SP1 may be shorted due to the step difference from the lower metal layer BML. Accordingly, as the first oxide semiconductor pattern SP1 is formed to be thicker than a specific thickness range, the first oxide semiconductor pattern SP1 may be stabilized in structure.

According to an embodiment, the thickness of the second oxide semiconductor pattern SP2 may be less than or equal to about 200 Å. In case that the thickness of the second oxide semiconductor pattern SP2 is over a specific range, an ability to control the movement of charges may be degraded. In other words, in case that the second oxide semiconductor pattern SP2 is formed with a thickness greater than a specific range, the mobility of the charges may be excessively increased, thereby causing a leakage current. As the second oxide semiconductor pattern SP2 is formed with a thickness thinner than the specific range, the second transistor TR2 may have a short-channel characteristic while more suppressing the leakage current. Accordingly, an improved on-off characteristic may be exhibited, and a display panel having a higher resolution may be provided.

The first transistor TR1 functioning as a driving transistor T11 illustrated in FIGS. 5A to 5C may have a driving range wider than a driving range of the second transistor TR2 functioning as a switching transistor T22 illustrated in FIGS. 5A to 5C. The first channel region A1 of the first transistor TR1 may have a multi-layer structure in which different materials are stacked each other. Accordingly, the driving range of the first channel region A1 may be increased than a driving range of the second channel region A2 having a single-layer structure. According to an embodiment, the first channel region A1 may have a driving range of at most 0.39 V. Accordingly, the pixel PX (see FIG. 4) may readily express various grayscale levels.

As described above, the first insulating pattern 31 and the second insulating pattern 32 may be connected to each other to be provided in the form of a layer having an integral shape. In other words, the third insulating layer 30 may be provided in the form of one insulating layer having an integral shape, instead of multiple split insulating patterns 31 and 32, but the disclosure is not limited thereto.

The fourth insulating layer 40 may cover the transistors TR1 and TR2. The fourth insulating layer 40 may include a silicon oxide, a silicon nitride, or a silicon oxy nitride, which are sequentially stacked on each other. The fourth insulating layer 40 may cover top surfaces of the first gate G1 and the second gate G2, and may cover top surfaces of the first oxide semiconductor pattern SP1 and the second oxide semiconductor pattern SP2.

The circuit element layer DP-CL may further include multiple connecting electrodes CN1, CN2, CN3, and CN4. The first connecting electrode CN1 may be connected to the first source region S1 of the first transistor TR1, and the second connecting electrode CN2 may be connected to the first drain region D1 of the first transistor TR1. The third connecting electrode CN3 may be connected to the second source region S2 of the second transistor TR2, and the fourth connecting electrode CN4 may be connected to the second drain region D2 of the second transistor TR2.

The lower metal layer BML may be electrically connected to the first source region S1. In other words, the first connecting electrode CN1 may be connected to the first source region S1 of the first transistor TR1 and the lower metal layer BML. Accordingly, the driving range of the first channel region A1 may be widened. However, the disclosure is not limited thereto. In another embodiment, the lower metal layer BML may be connected to the first gate G1 or the first drain region D1 of the first transistor TR1, may be electrically floated, receive a constant voltage, or may be omitted.

The fifth insulating layer 50 may be disposed on the fourth insulating layer 40 and cover the connecting electrodes CN1, CN2, CN3, and CN4. The light emitting element OLED may be connected to the circuit element layer DP-CL through a contact hole formed through the fifth insulating layer 50.

According to an embodiment, each of the first to fifth insulating layers 10, 20, 30, 40, and 50 may include an inorganic layer and/or an organic layer. For example, the first insulating layer 10 and the second insulating layer 20 may include a silicon nitride and/or a silicon oxide, and each of the first to third insulating patterns 31 and 32 constituting the third insulating layer 30 may include a silicon oxide. The fourth insulating layer 40 may include a silicon oxynitride layer and a silicon nitride layer sequentially stacked on each other, and the fifth insulating layer 50 may include an organic layer. However, the disclosure is not limited thereto. For example, the material or the stack form of each of the first to fifth insulating layers 10, 20, 30, 40, and 50 may be variously changed.

The display element layer DP-OLED may be disposed on the circuit element layer DP-CL. The display element layer DP-OLED may include the light emitting element OLED and a pixel defining layer PDL. The light emitting element OLED may include a first electrode E1, a hole control layer HCL, a light emitting layer EML, an electronic control layer ECL, and a second electrode E2.

The first electrode E1 may be disposed on the fifth insulating layer 50. The first electrode E1 may be connected to the third connecting electrode CN3 through the fifth insulation layer 50. However, the disclosure is not limited thereto. In another embodiment, the first electrode E1 may be connected through a separate additional connecting electrode, and may be directly connected to the second source region S2 of the second transistor TR2.

The pixel defining layer PDL may be disposed on the fifth insulating layer 50. The pixel defining layer PDL may expose at least a portion of the first electrode E1. In other words, an opening may be defined in the pixel defining layer PDL to expose a specific portion of the first electrode E1.

The hole control layer HCL may be disposed on the first electrode E1 and the pixel defining layer PDL. The hole control layer HCL may be disposed in the light emitting region and the non-light emitting region in common. The hole control layer HCL may include a layer having a higher hole mobility to facilitate the movement of holes to the light emitting layer EML from the first electrode E1. For example, the hole control layer HCL may include at least one of a hole transport layer, a hole injection layer, and an electron blocking layer, and each layer may have a stack structure in a single layer or a multi-layer.

The light emitting layer EML may be disposed on the hole control layer HCL. The light emitting layer EML may be disposed in a region corresponding to the opening of the pixel defining layer PDL. The light emitting layer EML may include an organic material and/or an inorganic material. The light emitting layer EML may generate one of a red light, a green light, and a blue light.

The electronic control layer ECL may be disposed on the light emitting layer EML and the hole control layer HCL. The electronic control layer ECL may be disposed in the light emitting region and the non-light emitting region in common. The electronic control layer ECL may include a layer having a higher electron mobility to facilitate the movement of electrons to the light emitting layer EML from the second electrode E2. For example, the hole control layer ECL may include at least one of a hole transport layer, a hole injection layer, and an electron blocking layer, and each layer may have a stack structure in a single layer or a multi-layer.

The second electrode E2 may be disposed on the electron control layer ECL. The second electrode E2 may be disposed in common in the pixels PX. In other words, the second electrode E2 may have an integral shape on the light emitting layers EML of the pixels PX in common. However, the disclosure is not limited thereto. In another embodiment, the second electrode E2 may be provided in the form of split pattern in each of the pixels PX. The second electrode E2 may have a semi-transmissive property or a transmissive property. For example, the second electrode E2 may be provided in various forms, such as a transparent conductive oxide layer, a metal layer having a thin-film thickness and a transmissive property, or a layer having a stack structure of a metal layer/oxide layer. In case that the light emitting element OLED has a bottom light emitting structure, the second electrode E2 may be a reflective electrode.

The encapsulating layer TFE may be disposed on the display element layer DP-OLED. The encapsulating layer TFE may include an inorganic layer and an organic layer. Although the encapsulating layer TFE is illustrated in the form of a stack structure in which a first inorganic layer IL1, an organic layer OL, and a second inorganic layer IL2 are sequentially stacked, the disclosure is not limited thereto, and the stack structure of layers forming the encapsulating layer TFE may be variously changed.

The first inorganic layer IL1 and the second inorganic layer IL2 may include an inorganic material and protect pixels from moisture/oxygen. The first inorganic layer IL1 and the second inorganic layer IL2 may include a same material or different materials. The organic layer OL may include an organic material, and may protect the display element layer DP-OLED or the circuit element layer DP-CL from foreign substances.

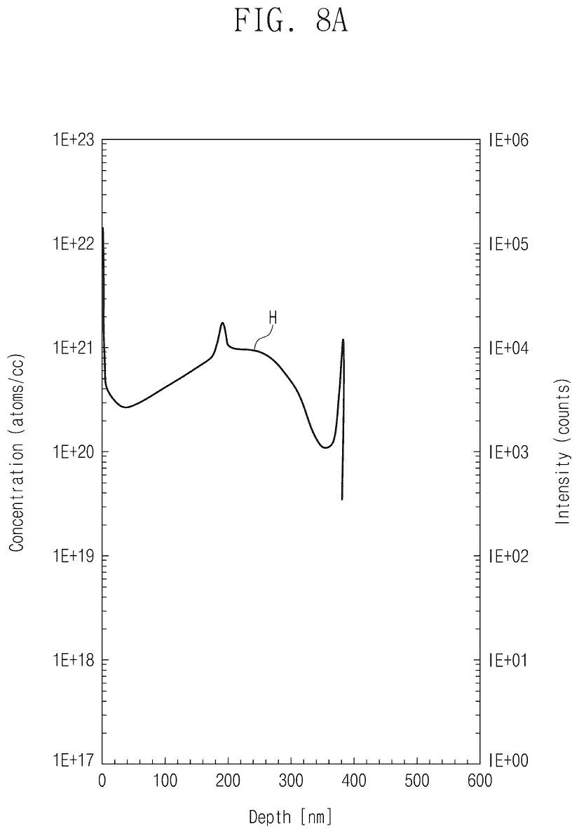

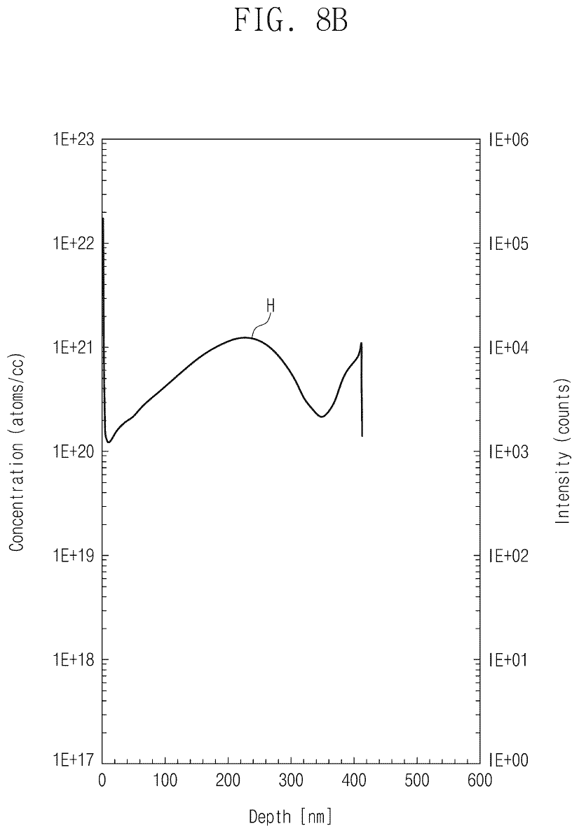

FIGS. 8A and 8B are secondary ion mass spectroscopy (SIMS) graphs illustrating the change in content of hydrogen in the first channel region A1 of the first transistor TR1 and the second channel region A2 of the second transistor TR2 according to the disclosure.

FIG. 8A is a SIMS graph as a function of a thickness of the first channel region A1 of the first transistor TR1 in a multi-layer structure, and FIG. 8B is a SIMS graph as a function of a thickness of the second channel region A2 of the second transistor TR2 in a single-layer structure. Hereinafter, the disclosure will be described with reference to FIGS. 8A and 8B.

Referring to FIG. 8A, it may be recognized that the peak of the hydrogen H is formed on the interface between the first oxide semiconductor layer SL1 and the second oxide semiconductor layer SL2, as the first channel region A1 in the multi-layer structure including the first oxide semiconductor layer SL1 and the second oxide semiconductor layer SL2 is formed. As hydrogen is present on the interface, the defects may be passivated. Accordingly, since the stability of the threshold voltage of the first transistor TR1 is improved, the wider driving range of a voltage may be shown.

Referring to FIG. 8B, it may be recognized that the content of hydrogen is continuously measured without the peak of hydrogen, as the second channel region A2 including the oxide semiconductor layer SSL in the single-layer structure is formed. In other words, the second channel region A2 may be continuously formed without the peak of hydrogen. Accordingly, the mobility of charges may be improved. Accordingly, the short-channel characteristic of the second transistor TR2 may be ensured.

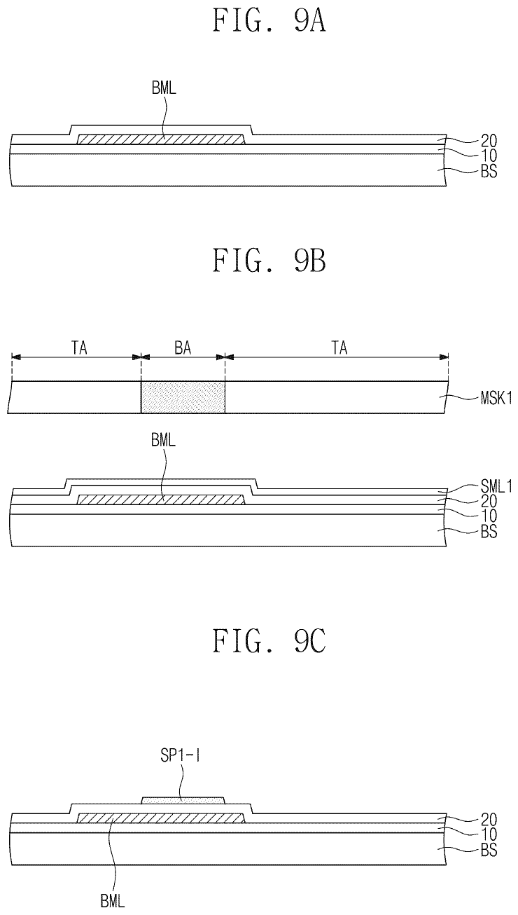

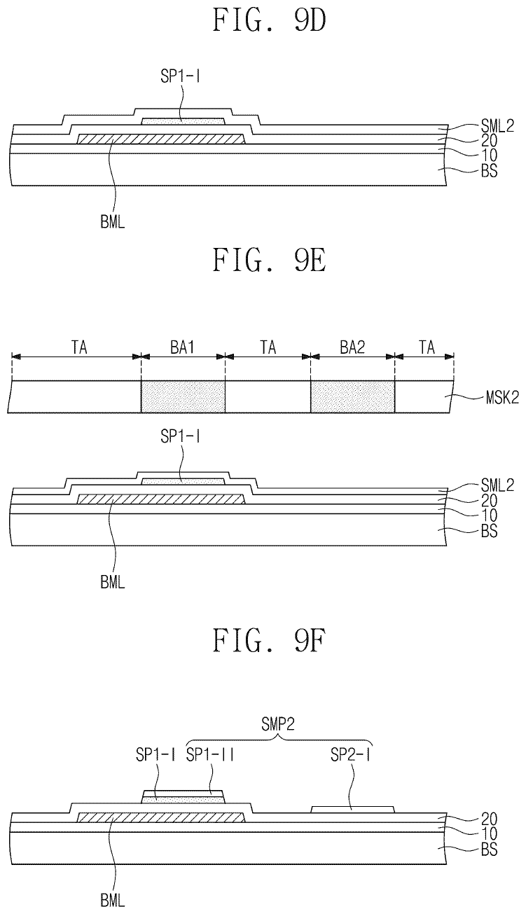

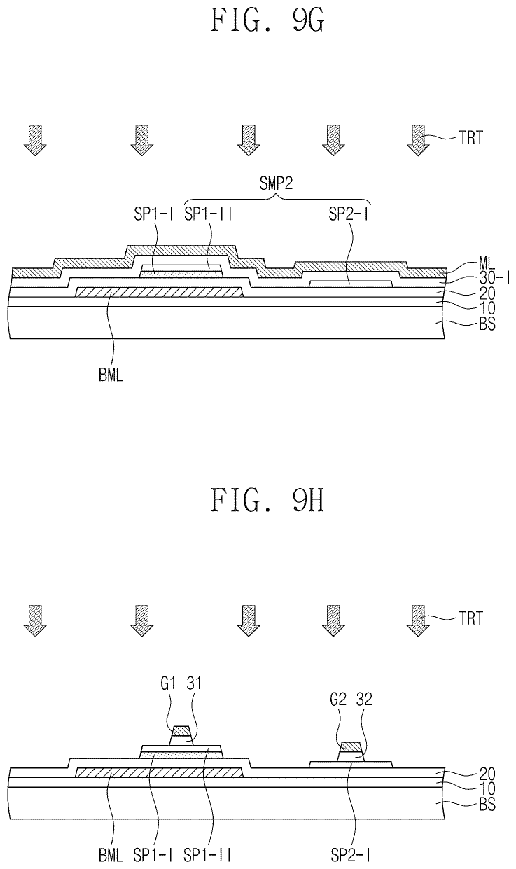

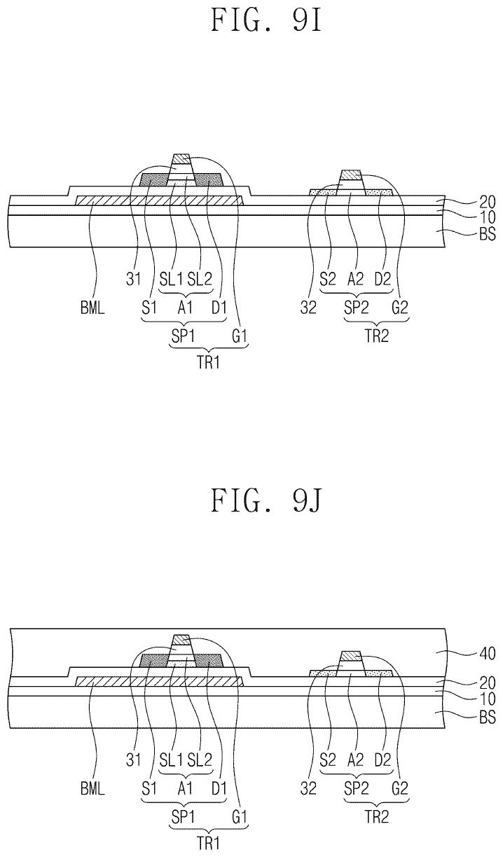

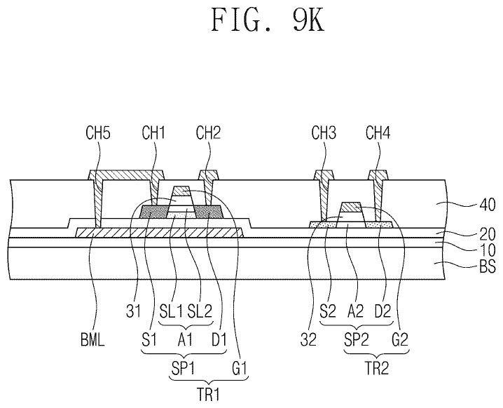

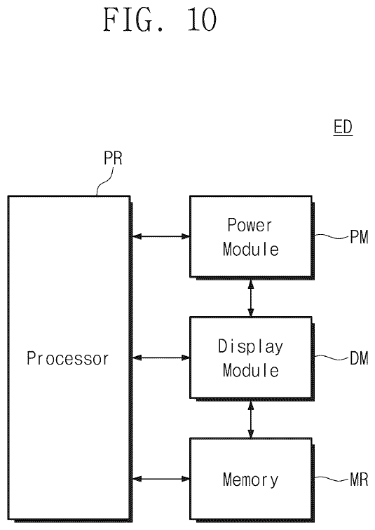

FIGS. 9A to 9K are schematic cross-sectional views illustrating a method for manufacturing a display panel according to an embodiment of the disclosure. Hereinafter, the disclosure will be described with reference to FIGS. 9A and 9K. The same components as components described with reference to FIGS. 1 to 8B will be assigned to the same reference numerals as those of the components described with reference to FIGS. 1 to 8B, and the duplicated description will be omitted to avoid redundancy.

Referring to FIG. 9A, the first insulating layer 10, the second insulating layer 20, and the lower metal layer BML may be formed on the base layer BS. The first insulating layer 10 may be formed by depositing or coating an insulating material on the base layer BS. The lower metal layer BML may be formed by depositing a conductive material on the first insulating layer 10 and patterning the result structure. However, the disclosure is not limited thereto. In another embodiment, the lower metal layer BML may be formed of an insulating material such as a black matrix or through a solution process such as a coating process, in addition to the deposition process. Thereafter, the second insulating layer 20 may be formed by depositing or coating an insulating material, to cover the lower metal layer BML. The second insulating layer 20 may include a barrier layer or a buffer layer. In an embodiment, the second insulating layer 20 may further include a buffer layer to cover the base layer BS and the first insulating layer 10.

Referring to FIGS. 9B and 9C, a first initial semiconductor pattern SP1-I may be formed on the second insulating layer 20. The first initial semiconductor pattern SP1-I may be patterned using a first mask MSK1, after forming a preliminary first oxide semiconductor layer SML1 on the second insulating layer 20. The preliminary first oxide semiconductor layer SML1 may include an indium-gallium-zinc oxide (IGZO). The preliminary first oxide semiconductor layer SML1 may be deposited to have a thickness greater than or equal to about 50 Å.

In the preliminary first oxide semiconductor layer SML1, a portion corresponding to a blocking region BA of the first mask MSK1 may remain to form the first initializing semiconductor pattern SP1-I, and a portion corresponding to a transmissive region of the first mask MSK1 may be removed. For example, the thickness of the first initial semiconductor pattern SP1-I may be greater than or equal to about 50 Å. The first initial semiconductor pattern SP1-I may be formed in a region overlapping the lower metal layer BML in a plan view. However, the disclosure is not limited thereto. For example, the first initial semiconductor pattern SP1-I may be obtained through various patterning manners, and the disclosure is not limited to any one embodiment.

Referring to FIG. 9D, a preliminary second oxide semiconductor layer SML2 may be formed. The preliminary second oxide semiconductor layer SML2 and the preliminary first oxide semiconductor layer SML1 may include different oxide. In an embodiment, the preliminary second oxide semiconductor layer SML2 may include an indium-tin-gallium-zinc oxide (ITGZO). The preliminary second oxide semiconductor layer SML2 may be deposited to have a thickness less than or equal to about 200 Å.

The second oxide semiconductor layer SML2 may be formed on the second insulating layer 20 and the first initial semiconductor pattern SP1-I through a depositing process. In other words, the preliminary second oxide semiconductor layer SML2 may be formed while making contact with the first initial semiconductor pattern SP1-I.

Referring to FIGS. 9E and 9F, the second initial semiconductor pattern SMP2 may include a first region SP1-II overlapping the first initial semiconductor pattern SP1-I and a second region SP2-I not overlapping the first initial semiconductor pattern SP1-I in a plan view. The second initial semiconductor pattern SMP2 may be obtained using a second mask MSK2, after forming the preliminary second oxide semiconductor layer SML2. In the second initial semiconductor pattern SMP2, a portion corresponding to a first blocking region BA1 of the second mask MSK2 may remain, and a portion overlapping the first initial semiconductor pattern SP1-I may be formed as a first region SP1-II. In the second initial semiconductor pattern SMP2, a portion corresponding to a second blocking region BA2 of the second mask MSK2 may remain, and a portion in the non-overlap state with the first initial semiconductor pattern SP1-I may be formed as a second region SP2-I. The portion corresponding to the transmissive region TA of the second mask MSK2 may be removed. For example, the thickness of the second initial semiconductor pattern SMP2 may be less than or equal to about 200 Å.

According to an embodiment, the first region SP1-II and the second region SP2-I of the second initial semiconductor pattern SMP2 may be simultaneously formed by one mask MSK2. Accordingly, the first region SP1-II and the second region SP2-I of the semiconductor pattern SMP2 may be formed of a same material.

Referring to FIGS. 9A and 91, thereafter, the gates G1 and G2 and the insulating patterns 31 and 32 may be formed. An initial third insulating layer 30-1 and the metal layer ML may be sequentially formed on the second insulating layer 20 to cover the first initial semiconductor pattern SP1-I and the second initial semiconductor pattern SMP2. The initial third insulating layer 30-I may be formed by depositing or coating an insulating material, and the metal layer ML may be formed by depositing or coating a metal material. The metal layer ML may be formed of a material having conductivity in addition to metal, but the disclosure is not limited thereto.

The initial third insulating layer 30-I and the metal layer ML may undergo a treatment process TRT to form the first insulating pattern 31, the second insulating pattern 32, the first gate G1, and the second gate G2. According to an embodiment, the treatment process TRT may be an etching process. The first gate G1 and the second gate G2 may be formed from the metal layer ML using a mask (not illustrated). Thereafter, the first insulating pattern 31 and the second insulating pattern 32 may be formed by using each of the first gate G1 and the second gate G2 as a mask. Accordingly, the first insulating pattern 31 and the second insulating pattern 32 may have the form aligned with the first gate G1 and the second gate G2.

The first initial semiconductor pattern SP1-I and the second initial semiconductor pattern SMP2 may be reduced to the first oxide semiconductor pattern SP1 and the second oxide semiconductor pattern SP2 through the treatment process TRT. Portions, which are exposed without being covered by the first insulating pattern 31 and the second insulating pattern 32, and the first gate G1 and the second gate G2, of the first initial semiconductor pattern SP1-I and the second initial semiconductor pattern SMP2, may be reduced through the treatment process such that metal is precipitated. Accordingly, the sources S1 and S2 and the drains D1 and D2 having higher conductivity may be formed. Each of the sources S1 and S2 and the drains D1 and D2 may be formed of regions having an N-type dopant.

The first initial semiconductor pattern SP1-I and the first region SP1-II may be formed to the first oxide semiconductor pattern SP1 including a first source region S1, a first drain region D1, and a first channel region A1, and the second region SP2-I may be formed to the second oxide semiconductor pattern SP2 including the second source region S2, the second drain region D2, and the second channel region A2. The channels A1 and A2 of the first oxide semiconductor pattern SP1 and the second oxide semiconductor pattern SP2 may be self-aligned with the gates G1 and G2 and the insulating patterns 31 and 32.

According to an embodiment of the disclosure, the first transistor TR1 and the second transistor TR2 may be formed to include the oxide semiconductor patterns SP1 and SP2 on a same layer. However, the disclosure is not limited thereto. The positions or structures of the first transistor TR1 and the second transistor TR2 may be variously changed, and the disclosure is not limited to any one embodiment.

Thereafter, referring to FIG. 9J, the fourth insulating layer 40 may be formed. The fourth insulating layer 40 may be formed by depositing or coating an insulating material. Although not illustrated, the fourth insulating layer 40 may be formed by sequentially stacking multiple insulating layers. The fourth insulating layer 40 may be formed to cover the transistors TR1 and TR2.

Thereafter, referring to FIG. 9K, the connecting electrodes CN1, CN2, CN3, and CN4 may be formed. The contact holes CH1, CH2, CH3, and CH4 may be formed in the fourth insulating layer 40, and the connecting electrodes CN1, CN2, CN3, and CN4 may be connected to the relevant transistors TR1 and TR2 through the contact holes CH1, CH2, CH3, and CH4, respectively. According to an embodiment of the disclosure, a contact hole CH5 may be further formed through the second insulating layer 20 and the fourth insulating layer 40. The first connecting electrode CN1 may be additionally connected to the lower metal layer BML through the contact hole CH5. Accordingly, the first source S1 of the first transistor TR1 and the lower metal layer BML may be electrically connected to each other. However, the disclosure is not limited thereto. For example, the arrangement of the connecting electrodes CN1, CN2, CN3, and CN4 may be variously changed depending on the structures of the transistors TR1 and TR2, and at least a portion of the arrangement may be omitted or further added.

The display device according to embodiments may be applied to various electronic devices. The electronic device according to embodiments may include the display device and may further include modules or devices with additional functions other than the display device.

FIG. 10 is a block diagram of the electronic device according to an embodiment of the disclosure. Referring to FIG. 1, the electronic device ED may include a display module DM, a processor PR, a memory MR, and a power module PM.

The processor PR may include at least one of a central processing unit (CPU), an application processor (AP), a graphics processing unit (GPU), a communication processor (CP), an image signal processor (ISP), and a controller.

The memory MR may store data information required for the operation of the processor PR or the display module DM. When the processor PR executes an application stored in the memory MR, an image data signal and/or an input control signal may be transmitted to the display module DM, and the display module DM may process the received signals to output image information through a display screen.

The power module PM may include a power supply module, such as a power adapter or a battery device, and a power conversion module that converts power supplied by the power supply module to generate power required for the operation of the electronic device ED.

At least one of the components of the electronic device ED may be included in a display device according to embodiments. In addition, among individual modules that are functionally included within a single module, some may be included in the display device while others may be provided separately from the display device. As an example, the display device may include the display module DM, and the processor PR, the memory MR, and the power module PM may be provided as separate devices within the electronic device ED and may not be included in the display device.

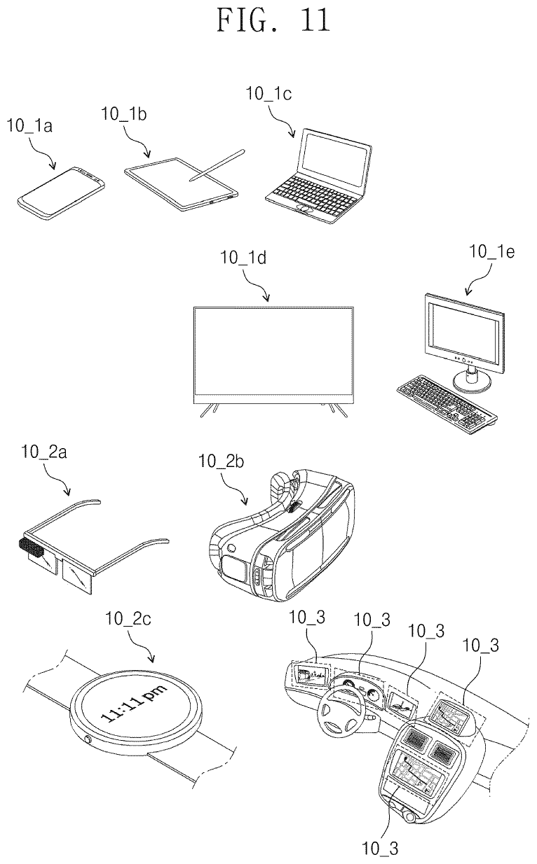

FIG. 11 is a view showing electronic devices according to embodiments of the disclosure.

Referring to FIG. 11, various electronic devices to which the display device according to embodiments is applied may include an electronic device for displaying images, such as a smartphone 10_1a, a tablet PC 10_1b, a laptop computer 10_1c, a television 10_1d, a desktop monitor 10_1e, etc., a wearable electronic device including a display module, such as a smart glasses 10_2a, a head-mounted display 10_2b, a smartwatch 10_2c, etc., or an in-vehicle electronic device ED_3 including a display module, such as an instrument panel, a center fascia, a dashboard-mounted center information display (CID), a room mirror display, etc.

As described above, the oxide semiconductor pattern of the first transistor may be formed to the oxide semiconductor layer in a multi-layer structure, and the oxide semiconductor pattern of the second transistor may be formed to the oxide semiconductor layer in a single-layer structure. The first transistor may include an oxide semiconductor layer in a multi-layer structure to reduce the risk of disconnection caused by the step difference from the metal layer disposed in the lower end portion of the first transistor. The first transistor may include different materials in a multi-layer structure to increase the driving voltage range of the first transistor. The single-layer structure oxide semiconductor layer of the second transistor may have higher mobility, and may be formed at a thickness for controlling the carrier of the channel region.

In other words, the first transistor having a wider driving voltage range and the second transistor having a higher mobility may be simultaneously provided. Accordingly, the expression of the lower grayscale level may be stably made, and the higher-resolution display panel may be readily designed. In addition, the process reliability for manufacturing the display panel may be improved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display panel comprising:
a light emitting element on a base layer; and
a pixel driving circuit electrically connected to the light emitting element, wherein
the pixel driving circuit comprises:
a first transistor comprising a first oxide semiconductor pattern; and
a second transistor comprising a second oxide semiconductor pattern,
the first oxide semiconductor pattern comprises a first channel region comprising a first oxide semiconductor layer and a second oxide semiconductor layer on the first oxide semiconductor layer, and
the second oxide semiconductor pattern comprises a second channel region comprising a single-layer oxide semiconductor layer.

2. The display panel of claim 1, wherein the first transistor further comprises:
a first gate disposed on the second oxide semiconductor layer and overlapping the first channel region in a plan view; and
a first gate insulating layer interposed between the first gate and the second oxide semiconductor layer.

3. The display panel of claim 1, wherein the second oxide semiconductor layer and the single-layer oxide semiconductor layer comprise a same semiconductor material.

4. The display panel of claim 1, wherein
the second transistor outputs a data voltage, and
the first transistor controls a driving current of the light emitting element to correspond to the data voltage.

5. The display panel of claim 1, wherein
the first oxide semiconductor pattern has a thickness greater than or equal to about 250 Å, and
the second oxide semiconductor pattern has a thickness less than or equal to about 200 Å.

6. The display panel of claim 1, wherein
the first oxide semiconductor layer and the second oxide semiconductor layer comprise different oxide semiconductors, and
the first oxide semiconductor layer comprises an indium-gallium-zinc oxide (IGZO).

7. The display panel of claim 6, wherein the second oxide semiconductor layer comprises indium, tin, gallium, zinc, and oxygen (ITGZO).

8. The display panel of claim 7, wherein in the second oxide semiconductor layer
the indium has a composition ratio in a range of about 60 w % to about 80 wt %,
the tin has a composition ratio in a range of about 0.5 wt % to about 8 wt %,
the gallium has a composition ratio in a range of about 5 wt % to about 15 wt %, and
the zinc has a composition ratio in a range of about 10 wt % to about 30 wt %.

9. The display panel of claim 1, further comprising:
a lower metal layer interposed between the base layer and the first transistor; and
a buffer layer interposed between the lower metal layer and the first oxide semiconductor pattern,
wherein the first oxide semiconductor pattern and the second oxide semiconductor pattern are disposed on the buffer layer.

10. The display panel of claim 9, wherein a source of the first transistor is electrically connected to the lower metal layer.

11. The display panel of claim 10, wherein a first connecting electrode that connects the source of the first transistor to the lower metal layer, and a second connecting electrode connected to a source of the second transistor are disposed on a same layer.

12. The display panel of claim 1, wherein each of the first transistor and the second transistor has a top-gate structure.

13. An electronic device comprising:
a light emitting element on a base layer; and
a pixel driving circuit electrically connected to the light emitting element, wherein
the pixel driving circuit comprises:
a first transistor comprising a first oxide semiconductor pattern; and
a second transistor comprising a second oxide semiconductor pattern, the first oxide semiconductor pattern comprises a first channel region comprising a first oxide semiconductor layer and a second oxide semiconductor layer on the first oxide semiconductor layer, and
the second oxide semiconductor pattern comprises a second channel region comprising a single-layer oxide semiconductor layer.

14. The electronic device of claim 13, wherein
the first oxide semiconductor pattern has a thickness greater than or equal to about 250 Å, and
the second oxide semiconductor pattern has a thickness less than or equal to about 200 Å.

15. The electronic device of claim 13, wherein
the first oxide semiconductor layer and the second oxide semiconductor layer comprise different oxide semiconductors,
the first oxide semiconductor layer comprises an indium-gallium-zinc-oxide (IGZO), and
the second oxide semiconductor layer comprises an indium-tin-gallium-zinc-oxide (ITGZO).

16. A method for manufacturing a display panel, the method comprising:
forming a first oxide semiconductor layer on a base layer;
forming a second oxide semiconductor layer comprising a first region overlapping the first oxide semiconductor layer and a second region non-overlapping the first oxide semiconductor layer in a plan view, on the base layer;
forming a first gate overlapping the first region of the second oxide semiconductor layer in a plan view;
forming a second gate overlapping the second region of the second oxide semiconductor layer in a plan view; and
forming an insulating layer to cover the first gate and the second gate.

17. The method of claim 16, wherein
the first oxide semiconductor layer has a thickness greater than or equal to about 50 Å, and
the second oxide semiconductor layer has a thickness less than or equal to about 200 Å.

18. The method of claim 16, further comprising:
forming a lower metal layer between the base layer and the first oxide semiconductor layer; and
forming a buffer layer to cover the lower metal layer and the base layer.

19. The method of claim 18, wherein the forming of the first gate comprises:
forming a first channel region overlapping the first gate in a plan view and a first source region and a first drain region disposed at opposite sides of the first channel region, from the second oxide semiconductor layer.

20. The method of claim 19, wherein
the lower metal layer overlaps the first region in a plan view, and
the lower metal layer and the first source region are electrically connected to each other.
